(19) United States
(12) Patent Application Publication
(10) Pub. No.: US 2012/0330582 A1
(43) Pub. Date: Dec. 27, 2012

(54) METHOD OF HIGH IMPEDANCE GROUNDFAULT DETECTION FOR DIFFERENTIAL PROTECTION OF OVERHEAD TRANSMISSION LINES

(75) Inventors: Andrzej Wiszniewski, Wroclaw (PL); Miroslaw Lukowicz, Wroclaw (PL); Marek Michalik, Wroclaww (PL); Andrzej Klimek, Surrey (CA)

(73) Assignees: Schneider Electric Energy UK Ltd., Telford (GB); Alstom Technology Ltd., Baden (CH)

(21) Appl. No.: 13/499,635

(22) PCT Filed: Sep. 30, 2009
(86) PCT No.: PCT/EP09/62669

§ 371 Date: Aug. 14, 2012

(51) Int. Cl. G01R 31/14; G06F 19/00

(52) U.S. Cl. 702/58

(57) ABSTRACT

The invention concerns a method of impedance groundfault detection for differential protection of an overhead transmission line in a three-phase high voltage electric power transmission system which comprises many lines (1,12) and many protection relays (2,4), which comprises the following steps: 1) in prefault condition: —measuring the differential current (I); —measuring the phase voltage (II) at the relay location; —measuring the phase current (III) the relay location; —calculating the differential admittance (IV), with the following equation: (formula (V)). With (VI): the positive sequence impedance of the line-protected. 2) In operating condition: —measuring the differential current (VII); —measuring the phase voltage (VIII) at the relay location; —measuring the phase current (IX) at the relay location; calculating the differential admittance (X), with the following equation: (formula (XI)); —detecting a high impedance groundfault detection, if the following formula is verified: (XII) with (XIII); B₀=the total line admittance.

$$\begin{matrix}{\underline{I}}_{dph}^{pre} & ( I ) \\ {\underline{U}}_{fph}^{pre} & ( II ) \\ {\underline{I}}_{fph}^{pre} & ( III ) \\ {\underline{Y}}_{d}^{pre} & ( IV ) \\ {\underline{Y}}_{d}^{pre} = \frac{{\underline{I}}_{dph}^{pre}}{{\underline{U}}_{fph}^{pre} - 0.5 {Z}_{L 1} {\underline{I}}_{fph}^{pre}} & ( V ) \\ {Z}_{L 1} & ( VI ) \\ {\underline{I}}_{dph} & ( VII ) \\ {\underline{U}}_{jph} & ( VIII ) \\ {\underline{I}}_{jph} & ( IX ) \\ {\underline{Y}}_{d} & ( X ) \\ {\underline{Y}}_{d} - \frac{{\underline{I}}_{dph}}{{\underline{U}}_{jph} - 0.5 {Z}_{L 1} {\underline{I}}_{jph}} & ( XI ) \\ abs ( {\underline{Y}}_{dN} ) > 0.75 {B}_{d} & ( XII ) \\ {\underline{Y}}_{dR} = {\underline{Y}}_{d} - {\underline{Y}}_{d}^{pre} & ( XIII )\end{matrix}$$

### BACKGROUND OF THE INVENTION

### Field of Invention

This invention relates to a method of high impedance groundfault detection for differential protection of overhead transmission lines.

The invention concerns the protection of high voltage transmission lines, in particular, the differential protection of such lines against groundfaults via very high fault impedance.

### DESCRIPTION OF THE RELATED ART

As described in document referenced [1] at the end of the description, a current differential protection system uses the electrical currents values information obtained from the protected line. Current differential protection requires a comparison of the currents entering and leaving a protected zone of the line. An example of a current differential protection system of an electrical transmission line is represented on FIG. 1. Protective relays 2, 4 are located at each end of a protected line 1. Such system may provide phase-segregated current differential protection. Circuit breakers 6, 8 and current transformers (CT) 7, 9 are associated, respectively, with relays 2, 4. A communication between the relays 2, 4 is made by a communication line 10.

In operation, each current transformer 7, 9 measures line current values at each ends of the protected line 1, and transmits those values to its associated relay. Each relay 2, 4 transmits those values to the relay located at the other end of the line 1, for each phase of the transmission line 1. Thus, the relay 2 will combine the current value iₛ(n), with a phase index n, given by the current transformer with the line current values iᵣ(n) sent from the remote relay 4, via the communication line 10. The sum of the current values is zero (iₛ(n)+iᵣ(n)=0) when an external fault appears (for example on an external line 12), while internal faults (on the protected line 1, between the relays 2, 4) will result in a non-zero combined currents ((iₛ(n)+iᵣ(n)≠0). Moreover, the sum of the currents values is equal to zero when there is no fault, neither on the external line 12 nor on the protected line 1.

Each relay 2, 4 controls its associated circuit breaker 6, 8 according to a stabilization function in form of an appropriate diff-bias characteristic which represents the tripping conditions of the circuit breakers 6, 8 associated with the relays 2, 4. The use of such a diff-bias characteristic prevents relays from undesired line tripping due to differential current resulting from not fully compensated charging current, CT errors, etc. A corresponding diff-bias characteristic is shown on FIG. 2. According to this characteristic, the trip criteria are:

for |i_{bias}|<I_{S2}, tripping when |i_{diff}|>k₁|i_{bias}|+I_{S1};

for |i_{bias}|>i_{S2}, tripping when |i_{diff}|>k₂|i_{bias}−(k₂−k₁)I_{S2}+I_{S1};

with:

|i_{bias}|=0.5(|iₛ|+|iᵣ|);

|i_{diff}|=|iₛ+iᵣ|;
k₁, k₂: bias percentages.

The values of I_{S1}, I_{S2}, k₁ and k₂ are chosen arbitrarily according to the characteristics of the line to be protected and the desired protection type

Although for most cases this standard protection arrangement is sufficient, there are still cases when the protection may fail.

The groundfaults via very high impedance usually occur when a broken conductor touches the ground. Such faults may not affect seriously the transmission line operation but, if uncleared, pose very high danger to human lives and environment and may develop into serious heavy current ones. So selective detection of such faults is a problem that relates to safety of transmission lines operation.

The type of fault that is defined by the term “high impedance groundfault” occurs, for example, when a tree has fallen over the conducting wires of a transmission line and arcing arises as a result of sparkover to the vegetation. An other example is a broken or fallen conducting primary wire which is brought into contact with the ground and thereby causes a ground fault condition.

Because of the high contact impedance which normally exists during faults of the above kind, the fault current is small and therefore often negligible. This also means that it will be difficult to reliably separate such faults from large load changes in the network. A consequence of this is that a high resistance fault may remain during a long period of time causing fire hazard and hazards to humans who come into contact with or in the vicinity of the conductor. Usually, this type of fault is discovered only during the continuous routine inspection of the conductor.

Ever since the childhood of electrical engineering, it has been a desire to be able to delect the type of fault described above. Consequently, there have been a large number of different approaches to solve this problem. One of the reasons for this is that the neutral point of the networks in relation to ground is treated in different ways. Keeping pace with the general technical development, the technical solutions to this problem have also undergone great changes. Previous classical, analog solution principles have nowadays given way to more or less sophisticated solutions based on digital data processing techniques performed by computers, approximation of measured signal values to mathematical functions, estimation of parameters included, numerical technique and statistical methods.

The existing methods of fault detection based on measurement of differential current are not sensitive enough to detect groundfaults via high impedance exceeding 200 Ohms.

The document referenced [2] describes a protection device for high impedance ground faults in a power network, the fault detection principle of which is based on an indirect study of non-harmonic frequency components of the phase currents. When such a fault has occurred, a considerable change of the energy contents of these frequency current components arises. This change can be detected by the device. If by comparison between digitized input signals and a harmonic Fourier model of the same signals, i.e. generation of the residuals of the system, it is found that a difference exists, and if the corresponding loss function V, for a certain time exceeds a lower limit value—on condition that a zero sequence current exists—then the device indicates a high impedance ground fault on any of the phases of the network.

The document referenced [3] relates to a method for detection of high impedance groundfaults in a medium-voltage network, wherein the method, the degree of unsymmetry and/or the line-to-ground admittance as well as the zero-sequence voltage of each sending end are determined. For the value of the line-to-ground admittance and the degree of unsymmetry of each sending end are determined a reference value on the basis of measurement information obtained by means of an artificial deviation of the neutral voltage performed in a reference connection status. In a memory are stored as reference values the values of the line-to-ground admittance and the degree of unsymmetry of each sending end, as well as the normal-connection status values of the zero-sequence voltage and the zero-sequence currents of the sendings ends and the zero-sequence current of the feeding power source. The zero-sequence voltage is monitored at least essentially continuously and, if said zero-sequence voltage changes by more than a predetermined limit difference, for each one of the sending ends are computed new values of line-to-ground admittance and degree of unsymmetry, the most recently computed values of the line-to-ground admittance are compared with the reference values. From the comparison is determined whether the difference therebetween exceeds the inaccuracy of the measurement technique used, whereby if the comparison gives a value greater than said measurement inaccuracy, it is checked for instance on the basis of the change in the entire network's summed line-to-ground admittance, which is computable from zero-sequence current of the feeding power source, whether a changed has occurred in the connection status of the network end. If so, the most recently measured values of the line-to-ground admittance and degree of unsymmetry are stored as new reference values, while, if no change has occurred in the network connection status, a ground fault is indicated.

The above two documents are relative to median voltage networks (distribution), when the purpose of the invention method is to protect high voltage networks (transmission).

### SUMMARY OF THE INVENTION

The invention concerns a method of high impedance groundfault detection for differential protection of an overhead transmission line in a three-phase high voltage electric power transmission system which comprises many lines and many protection relays, characterized in that it comprises the following steps:

1) in prefault condition:
measuring the differential current I_{dph}^{pre}
measuring the phase voltage U_{fph}^{pre} at the relay location
measuring the phase current I_{fph}^{pre} at the relay location
calculating the differential admittance Y_{d}^{pre}, with the following equation:

$${\underline{Y}}_{d}^{pre} = \frac{{\underline{I}}_{dph}^{pre}}{{\underline{U}}_{fph}^{pre} - 0.5 {Z}_{L 1} {\underline{I}}_{fph}^{pre}}$$

With Z_{L1} the positive sequence impedance of the line-protected.
2) In operating condition:
measuring the differential current I_{dph}
measuring the phase voltage U_{fph} at the relay location
measuring the phase current I_{fph} at the relay location
calculating the differential admittance Y_{d}, with the following equation:

$${\underline{Y}}_{d} = \frac{{\underline{I}}_{dph}}{{\underline{U}}_{fph} - 0.5 {Z}_{L 1} {\underline{I}}_{fph}}$$

detecting a high impedance groundfault, if the following formula is verified:

abs(Y_{dR})>0.75B₀

With

Y_{dR}=Y_{d}−Y_{d}^{pre}

B₀=the total line admittance
Advantageously abs(Y_{dR})>B₀

With the invention method, it is possible to obtain a remarkably increased sensitivity of high resistance groundfault detection.

### BRIEF DESCRIPTION OF THE DRAWINGS

FIG. 1 shows a current differential protection system of a electrical transmission line of the prior art.

FIG. 2 shows a stabilisation function of such a current differential protection relay.

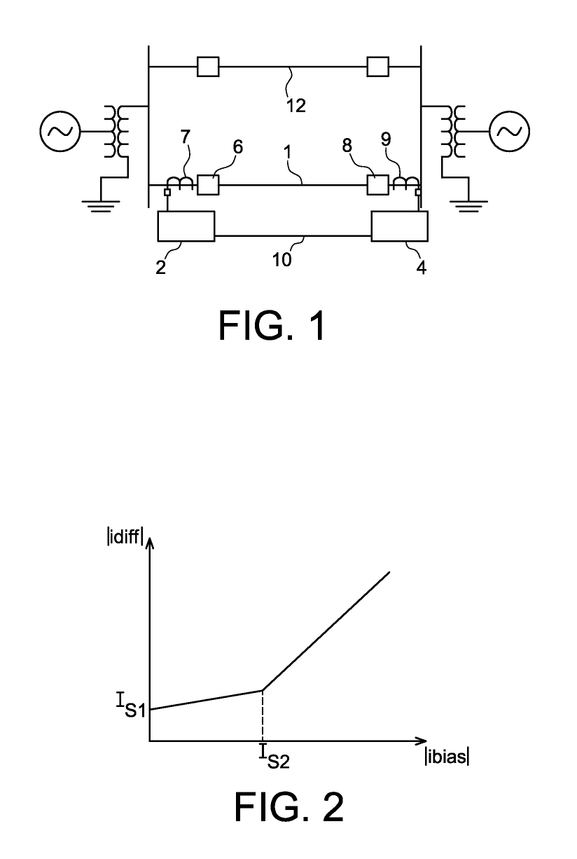

### DESCRIPTION OF THE PREFERRED EMBODIMENTS

The invention method is based on determination of increment of the differential admittance, understood as the ratio of the differential current, which is the difference of phase currents flowing at both ends of a line, to phase voltage referred to the middle of a line, and calculated in faulty and in pre-fault conditions.

Such an approach ensures good compensation of phase-to-ground capacitive current. As a result sensitivity of the protection increases remarkably, thus enabling detection of groundfaults through high resistances up to 1 kOhm.

The method is based on determination of differential admittance Y_{dR} which is given by the simple formula:

Y_{dR}=Y_{d}−Y_{d}^{pre} (1)

where:
Y_{d}: the differential admittance measured by the relay in faulty conditions
Y_{d}^{pre}: the differential admittance measured by the relay in pre-fault conditions.

The differential admittance Y_{d} is determined with respect to the phase voltage in the middle of the line according to the equation:

$${\underline{Y}}_{d} = \frac{{\underline{I}}_{dph}}{{\underline{U}}_{fph} - 0.5 {Z}_{L 1} {\underline{I}}_{fph}} \qquad ( 2 )$$

where:

I_{dph}: the differential current in faulty phase
U_{fph}: the faulty phase voltage at the relay location
Z_{L1}: the positive sequence impedance of the line protected
I_{fph}: the faulty phase current at the relay location

and:

$${\underline{Y}}_{d}^{pre} = \frac{{\underline{I}}_{dph}^{pre}}{{\underline{U}}_{fph}^{pre} - 0.5 {Z}_{L 1} {\underline{I}}_{fph}^{pre}} \qquad ( 3 )$$

where the respective currents and voltage as in (2) are measured in pre-fault conditions.

The high impedance groundfault can be detected using one of the following formula:

abs(Y_{dR})>0.75B₀

where

B₀—the total line susceptance

Advantageously abs(Y_{dR})>B₀

### REFERENCES

[1] <<Unit Protection of feeders>> (NPAG Download, 2008, Areva T&D, chapter 10, pages 153-168)
[2] EP 0 307 826
[3] WO 01/22104

1. A method of impedance groundfault detection for differential protection of an overhead transmission line in a three-phase high voltage electric power transmission system comprising a plurality of lines and a plurality of protection relays, the method comprising:
in a prefault condition:
measuring the differential current I_{dph}^{pre};
measuring the phase voltage U_{fph}^{pre} at the relay location;
measuring the phase current I_{fph}^{pre} at the relay location;
calculating the differential admittance Y_{d}^{pre}, with the following equation:
$${\underline{Y}}_{d}^{pre} = \frac{{\underline{I}}_{dph}^{pre}}{{\underline{U}}_{fph}^{pre} - 0.5 {Z}_{L 1} {\underline{I}}_{fph}^{pre}}$$
wherein Z_{L1} corresponds to the positive sequence impedance of the line protected;
and in a fault condition:
measuring the differential current I_{dph};
measuring the phase voltage U_{fph} at the relay location;
measuring the phase current I_{fph} at the relay location;
calculating the differential admittance Y_{d}, with the following equation:
$${\underline{Y}}_{d} = \frac{{\underline{I}}_{dph}}{{\underline{U}}_{fph} - 0.5 {Z}_{L 1} {\underline{I}}_{fph}}$$
detecting a high impedance groundfault, if the following formula is verified:
abs(Y_{dR})>0.75B₀
with Y_{dR}=Y_{d}−Y_{d}^{pre}, and
B₀=the total line admittance

2. The method of claim 1, wherein:
abs(Y_{dR})>B₀

3. A method of impedance groundfault detection for differential protection of an overhead transmission line in a three-phase high voltage electric power transmission system comprising a plurality of lines and a plurality of protection relays, the method comprising:
in a prefault condition:
measuring the differential current I_{dph}^{pre};
measuring the phase voltage U_{fph}^{pre} at the relay location;
measuring the phase current I_{fph}^{pre} at the relay location;
calculating the differential admittance Y_{d}^{pre}, with the following equation:
$${\underline{Y}}_{d}^{pre} = \frac{{\underline{I}}_{dph}^{pre}}{{\underline{U}}_{fph}^{pre} - 0.5 {Z}_{L 1} {\underline{I}}_{fph}^{pre}}$$
wherein Z_{L1} corresponds to the positive sequence impedance of the line protected;
and in a fault condition:
measuring the differential current I_{dph};
measuring the phase voltage U_{fph} at the relay location;
measuring the phase current I_{fph} at the relay location;
calculating the differential admittance Y_{d}, with the following equation:
$${\underline{Y}}_{d} = \frac{{\underline{I}}_{dph}}{{\underline{U}}_{fph} - 0.5 {Z}_{L 1} {\underline{I}}_{fph}}$$
detecting a high impedance groundfault, if the following formula is verified:
$$abs ( {\underline{Y}}_{dR} ) > \frac{0.75}{{R}_{F ma x}}$$
with Y_{dR}=Y_{d}−Y_{d}^{pre}, and
R_{Fmax}=the maximum value of the fault resistance to be detected

4. The method of claim 1, wherein:
$$abs ( {\underline{Y}}_{dR} ) > \frac{1}{{R}_{F ma x}}$$
